(19) United States
(12) Patent Application Publication
(10) Pub. No.: US 2024/0026198 A1
(43) Pub. Date: Jan. 25, 2024

(54) BORON NITRIDE POWDER, HEAT DISSIPATION SHEET, AND METHOD FOR PRODUCING HEAT DISSIPATION SHEET

(71) Applicant: DENKA COMPANY LIMITED, Tokyo (JP)

(72) Inventors: Kosuke WADA, Nagasu-machi (JP); Kiyotaka FUJI, Chikuzen-machi (JP)

(73) Assignee: DENKA COMPANY LIMITED, Tokyo (JP)

(21) Appl. No.: 18/266,099

(22) PCT Filed: Dec. 17, 2021
(86) PCT No.: PCT/JP2021/046762

§ 371 Date: Jun. 8, 2023

(30) Foreign Application Priority Data
Jan. 6, 2021 (JP) 2021-000881

(51) Int. Cl. C09K 5/00; C01B 21/064; C08K 3/38; C08J 5/18; C08J 3/20

(52) U.S. Cl. CPC C09K 5/00; C01B 21/064; C08K 3/38; C08J 5/18; C08J 3/203; C01P 2004/51; C01P 2006/21; C01P 2004/50; C01P 2004/62; C01P 2004/61; C01P 2002/76; C01P 2006/32; C08K 2201/001; C08K 2003/385; C08K 2201/005; C08J 2383/04

(57) ABSTRACT

A boron nitride powder, containing at least an aggregated boron nitride particle formed by an aggregation of hexagonal boron nitride primary particles, the powder having a particle size distribution including at least a first maximum point, a second maximum point at which a particle size is larger than at the first maximum point, and a third maximum point at which a particle size is larger than at the second maximum point. The heat dissipation sheet is obtained by molding a heat conductive resin composition containing the boron nitride powder and a resin. The method for producing a heat dissipation sheet includes blending the boron nitride powder and a resin to prepare a heat conductive resin composition, molding the heat conductive resin composition into a sheet shape to prepare a heat conductive resin composition sheet, and heating and pressurizing the heat conductive resin composition sheet under a vacuum.

### TECHNICAL FIELD

The present invention relates to a boron nitride powder, containing at least an aggregated boron nitride particle formed by an aggregation of hexagonal boron nitride primary particles, a heat dissipation sheet obtained by molding a heat conductive resin composition containing the boron nitride powder and a resin, a heat dissipation sheet obtained by molding a heat conductive resin composition, and a method for producing the heat dissipation sheet.

### BACKGROUND ART

In heat generating electronic components such as a power device, a transistor, a thyristor, and a CPU, how the heat generated during use thereof is efficiently dissipated is an important issue. Conventionally, as the heat dissipation measure, generally (1) heat conductivity of an insulating layer of a printed-wiring board onto which the heat generating electronic component is to be mounted has been improved, or (2) the heat generating electronic component or a printed-wiring board onto which the heat generating electronic component was mounted has been mounted onto a heat sink via thermal interface materials having electrical insulation properties. As the insulating layer of the printed-wiring board and the thermal interface materials, a silicone resin or an epoxy resin filled with ceramic powder is used.

As the ceramic powder, boron nitride powder having properties such as high heat conductivity, high insulation property, and low relative permittivity is attracting attention. For example, PTL 1 discloses a boron nitride powder formed by an aggregation of primary particles of boron nitride, having a peak A existing in a range of 5 μm or more and less than 30 μm and a peak B existing in a range of 50 μm or more and less than 100 μm, in a particle size distribution based on volume.

### CITATION LIST

### Patent Literature

PTL 1: JP 2020-164365 A

### SUMMARY OF INVENTION

### Technical Problem

Using the boron nitride powder described in PTL 1, a heat dissipation sheet excellent in heat conductivity can be obtained. However, in accordance with recent size reduction of electronic devices and increase in heat value of heat generating electronic components, a heat dissipation sheet more excellent in heat conductivity is required.

Accordingly, it is an object of the present invention to provide a boron nitride powder for obtaining a heat dissipation sheet excellent in heat conductivity, the heat dissipation sheet excellent in heat conductivity, and a method for producing the heat dissipation sheet excellent in heat conductivity.

### Solution to Problem

The present inventors have intensively studied and have found that boron nitride powder having a specific particle size distribution can solve the above problem.

The present invention is based on the above knowledge and its gist is as below.
[1] A boron nitride powder, containing at least an aggregated boron nitride particle formed by an aggregation of hexagonal boron nitride primary particles, the boron nitride powder having a particle size distribution including at least a first maximum point, a second maximum point at which a particle size is larger than at the first maximum point, and a third maximum point at which a particle size is larger than at the second maximum point, in which the particle size at the first maximum point is 0.4 μm or more and less than 10 μm, the particle size at the second maximum point is 10 μm or more and less than 40 μm, and the particle size at the third maximum point is 40 μm or more and 110 μm or less.
[2] The boron nitride powder according to the above [1], in which an absolute value of a difference between a particle size at which an integrated quantity of a frequency in the particle size distribution of the boron nitride powder reaches 10%, and a particle size at a minimum point between a maximum point at which a particle size is the smallest and a maximum point at which a particle size is the second smallest in the particle size distribution of the boron nitride powder is 3 to 30 μm.
[3] The boron nitride powder according to the above [1] or [2], in which a maximum point adjacent to the first maximum point is the second maximum point, a maximum point adjacent to the second maximum point is the third maximum point, and an absolute value of a difference between a particle size at a first minimum point existing between the first maximum point and the second maximum point, and a particle size at a second minimum point existing between the second maximum point and the third maximum point is 15 to 60 μm.
[4] The boron nitride powder according to any one of the above [1] to [3], in which a peak including the third maximum point has a half-value width of 20 to 60 μm.
[5] The boron nitride powder according to any one of the above [1] to [4], in which the aggregated boron nitride particle has a crushing strength of 5 to 18 MPa.
[6] A heat dissipation sheet obtained by molding a heat conductive resin composition containing the boron nitride powder according to any one of the above [1] to [5] and a resin.
[7] A method for producing a heat dissipation sheet, including a step of blending the boron nitride powder according to any one of the above [1] to [5] and a resin to prepare a heat conductive resin composition, a step of molding the heat conductive resin composition into a sheet shape to prepare a heat conductive resin composition sheet, and a step of heating and pressurizing the heat conductive resin composition sheet under a vacuum.

### Advantageous Effects of Invention

According the present invention, a boron nitride powder for obtaining a heat dissipation sheet excellent in heat conductivity, the heat dissipation sheet excellent in heat conductivity, and a method for producing the heat dissipation sheet excellent in heat conductivity can be provided.

### BRIEF DESCRIPTION OF DRAWINGS

FIG. 1 is a conceptual view of a particle size distribution of boron nitride powder according to the present invention.

### DESCRIPTION OF EMBODIMENTS

### [Boron Nitride Powder]

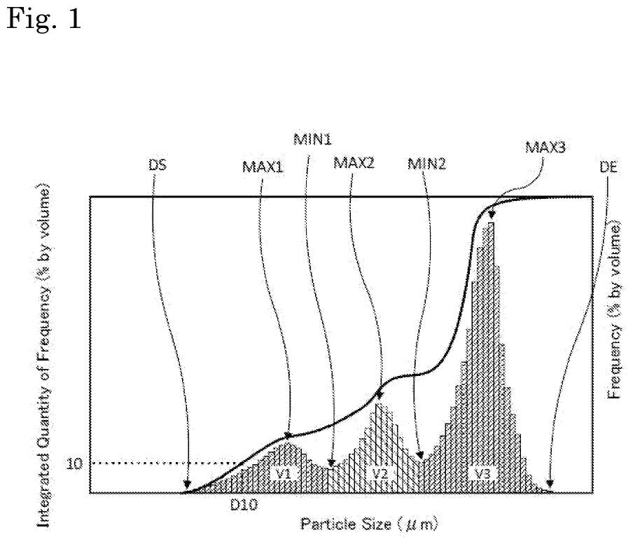

Referring to FIG. 1, the boron nitride powder according to the present invention will be explained. FIG. 1 is a conceptual view illustrating a particle size distribution of the boron nitride powder according to the present invention. In the particle size distribution illustrated in FIG. 1, the vertical axis is linear and the horizontal axis is logarithmic. The particle size distribution of the boron nitride powder illustrated in FIG. 1 is only a conceptual view and does not limit the boron nitride powder according to the present invention.

The boron nitride powder according to the present invention is a boron nitride powder containing at least an aggregated boron nitride particle formed by an aggregation of hexagonal boron nitride primary particles. As illustrated in FIG. 1, the particle size distribution of the boron nitride powder according to the present invention includes at least a first maximum point (MAX1), a second maximum point (MAX2) at which a particle size is larger than at the first maximum point (MAX1), and a third maximum point (MAX3) at which a particle size is larger than at the second maximum point (MAX2). In addition, the particle size at the first maximum point (MAX1) is 0.4 μm or more and less than 10 μm, the particle size at the second maximum point (MAX2) is 10 μm or more and less than 40 μm, and the particle size at the third maximum point (MAX3) is 40 μm or more and 110 μm or less. In this way, filling property of the boron nitride powder in the heat dissipation sheet can be improved and heat conductivity of the heat dissipation sheet can be made excellent. The particle size distribution of the boron nitride powder according to the present invention can be measured by the method of Examples described later.

As described above, the particle size distribution of the boron nitride powder according to the present invention includes at least a first maximum point (MAX1), a second maximum point (MAX2) at which the particle size is larger than at the first maximum point (MAX1), and a third maximum point (MAX3) at which the particle size is larger than at the second maximum point (MAX2). When the particle size distribution of the boron nitride powder does not include at least one maximum point among the first maximum point (MAX1), the second maximum point (MAX2), and the third maximum point (MAX3), filling property of the boron nitride powder in the heat dissipation sheet is deteriorated and heat conductivity of the heat dissipation sheet becomes poor.

The particle size at the first maximum point (MAX1) is 0.4 μm or more and less than 10 μm. When the particle size at the first maximum point (MAX1) is less than 0.4 μm or 10 μm or more, filling property of the boron nitride powder in the heat dissipation sheet is deteriorated and heat conductivity of the heat dissipation sheet becomes poor. From the above viewpoint, the particle size at the first maximum point (MAX1) is preferably 2.0 to 8.0 μm and more preferably 3.0 to 6.0 μm.

The particle size at the second maximum point (MAX2) is 10 μm or more and less than 40 μm. When the particle size at the second maximum point (MAX2) is less than 10 μm or 40 μm or more, filling property of the boron nitride powder in the heat dissipation sheet is deteriorated and heat conductivity of the heat dissipation sheet becomes poor. From the above viewpoint, the particle size at the second maximum point (MAX2) is preferably 15 to 36 μm and more preferably 18 to 30 μm.

The particle size at the third maximum point (MAX3) is 40 to 110 μm. When the particle size at the third maximum point (MAX3) is less than 40 μm or more than 110 μm, filling property of the boron nitride powder in the heat dissipation sheet is deteriorated and heat conductivity of the heat dissipation sheet becomes poor. From the above viewpoint, the particle size at the third maximum point (MAX3) is preferably 50 to 100 μm and more preferably 65 to 90 μm.

A maximum point adjacent to the first maximum point (MAX1) is the second maximum point (MAX2), a maximum point adjacent to the second maximum point (MAX2) is the third maximum point (MAX3), and an absolute value of a difference between a particle size at a first minimum point (MIN1) existing between the first maximum point (MAX1) and the second maximum point (MAX2), and a particle size at a second minimum point (MIN2) existing between the second maximum point (MAX2) and the third maximum point (MAX3) is preferably 15 to 60 μm. When the absolute value of the difference between the particle size at the first minimum point (MIN1) and the particle size at the second minimum point (MIN2) is 15 to 60 μm, filling property of the boron nitride powder in the heat dissipation sheet can be more improved and heat conductivity of the heat dissipation sheet can be made more excellent. From the above viewpoint, the absolute value of the difference between the particle size at the first minimum point (MIN1) and the particle size at the second minimum point (MIN2) is preferably 19 to 53 μm and more preferably 25 to 40 μm.

A peak including the third maximum point (MAX3) has a half-value width of preferably 20 to 60 μm. When the peak including the third maximum point (MAX3) has a half-value width of 20 to 60 μm, filling property of the boron nitride powder in the heat dissipation sheet can be more improved and heat conductivity of the heat dissipation sheet can be made more excellent. From the above viewpoint, the peak including the third maximum point (MAX3) has a half-value width of preferably 24 to 55 μm and more preferably 40 to 50 μm. The half-value width of the peak including the third maximum point (MAX3) is a width of the peak at a part where a frequency is the half value of the frequency at the third maximum point (MAX3).

An absolute value of a difference between a particle size at which an integrated quantity of a frequency in the particle size distribution of the boron nitride powder reaches 10%, and a particle size at a minimum point between a maximum point at which a particle size is the smallest and a maximum point at which a particle size is the second smallest in the particle size distribution of the boron nitride powder is preferably 3 to 30 μm. For example, in the particle size distribution of the boron nitride powder illustrated in FIG. 1, the sign D10 indicates the particle size at which the integrated quantity of the frequency reaches 10%, the maximum point at which the particle size is the smallest in the particle size distribution of the boron nitride powder is the first maximum point (MAX1), the maximum point at which the particle size is the second smallest in the particle size distribution of the boron nitride powder is the second maximum point (MAX2), and the minimum point between the maximum point at which the particle size is the smallest and the maximum point at which the particle size is the second smallest is the first minimum point (MIN1). When the absolute value of the difference between the above particle sizes is 3 to 30 μm, filling property of the boron nitride powder in the heat dissipation sheet can be more improved and heat conductivity of the heat dissipation sheet can be made more excellent. From the above viewpoint, the absolute value of the difference between the above particle sizes is preferably 5 to 24 μm and more preferably 6 to 15 μm.

An integrated quantity (V1) of a frequency between a peak start and a peak end in the peak including the first maximum point (MAX1) is preferably 2 to 25% by volume. When the integrated quantity (V1) is 2 to 25% by volume, filling property of the boron nitride powder in the heat dissipation sheet can be more improved and heat conductivity of the heat dissipation sheet can be made more excellent. From the above viewpoint, the integrated quantity (V1) is more preferably 5 to 20% by volume. The peak start in the peak including the first maximum point (MAX1) is a minimum point existing on the side where the particle size is smaller relative to the first maximum point (MAX1). When there is no minimum point on the side where the particle size is smaller relative to the first maximum point (MAX1), the peak start is the end (DS) of the particle size distribution on the side where the particle size is smaller. Further, the peak end in the peak including the first maximum point (MAX1) is a minimum point (MIN1) existing on the side where the particle size is larger relative to the first maximum point (MAX1). The integrated quantity (V1) of the frequency is a value obtained by subtracting the frequency of the particle size at the minimum point (MIN1) existing on the side where the particle size is larger relative to the first maximum point (MAX1) from the integrated quantity of the frequency of from the particle size at the minimum point existing on the side where the particle size is smaller relative to the first maximum point (MAX1) or the particle size at the end (DS) of the particle size distribution on the side where the particle size is smaller to the particle size at the minimum point (MIN1) existing on the side where the particle size is larger relative to the first maximum point (MAX1). Here, the reason for subtracting the frequency of the particle size at the minimum point (MIN1) existing on the side where the particle size is larger relative to the first maximum point (MAX1) is to prevent the frequency of the particle size at the minimum point (MIN1) existing on the side where the particle size is larger relative to the first maximum point (MAX1) from being included in both the integrated quantity of the frequency between the peak start and the peak end in the peak including the first maximum point (MAX1) and an integrated quantity of a frequency between a peak start and a peak end in the peak including the second maximum point (MAX2).

An integrated quantity (V2) of a frequency between a peak start and a peak end in the peak including the second maximum point (MAX2) is preferably 15 to 50% by volume. When the integrated quantity (V2) is 15 to 50% by volume, filling property of the boron nitride powder in the heat dissipation sheet can be more improved and heat conductivity of the heat dissipation sheet can be made more excellent. From the above viewpoint, the integrated quantity (V2) is more preferably 20 to 45% by volume. The peak start in the peak including the second maximum point (MAX2) is a minimum point (MIN1) existing on the side where the particle size is smaller relative to the second maximum point (MAX2). Further, the peak end in the peak including the second maximum point (MAX2) is a minimum point (MIN2) existing on the side where the particle size is larger relative to the second maximum point (MAX2). The integrated quantity (V2) of the frequency is a value obtained by subtracting the frequency of the particle size at the minimum point (MIN2) existing on the side where the particle size is larger relative to the second maximum point (MAX2) from the integrated quantity of the frequency of from the particle size at the minimum point (MIN1) existing on the side where the particle size is smaller relative to the second maximum point (MAX2) to the particle size at the minimum point (MIN2) existing on the side where the particle size is larger relative to the second maximum point (MAX2). Here, the reason for subtracting the frequency of the particle size at the minimum point (MIN2) existing on the side where the particle size is larger relative to the second maximum point (MAX2) is to prevent the frequency of the particle size at the minimum point (MIN2) existing on the side where the particle size is larger relative to the second maximum point (MAX2) from being included in both the integrated quantity of the frequency between the peak start and the peak end in the peak including the second maximum point (MAX2) and an integrated quantity of a frequency between a peak start and a peak end in the peak including the third maximum point (MAX3).

An integrated quantity (V3) of a frequency between a peak start and a peak end in the peak including the third maximum point (MAX3) is preferably 30 to 80% by volume. When the integrated quantity (V3) is 30 to 80% by volume, filling property of the boron nitride powder in the heat dissipation sheet can be more improved and heat conductivity of the heat dissipation sheet can be made more excellent. From the above viewpoint, the integrated quantity (V3) is more preferably 45 to 75% by volume. The peak start in the peak including the third maximum point (MAX3) is a minimum point (MIN2) existing on the side where the particle size is smaller relative to the third maximum point (MAX3). Further, the peak end in the peak including the third maximum point (MAX3) is a minimum point existing on the side where the particle size is larger relative to the third maximum point (MAX3). When there is no minimum point on the side where the particle size is larger relative to the third maximum point (MAX3), the peak end is the end (DE) of the particle size distribution on the side where the particle size is larger. The integrated quantity (V3) of the frequency is a value obtained by subtracting the frequency of the particle size at the minimum point existing on the side where the particle size is larger relative to the third maximum point (MAX3) from the integrated quantity of the frequency of from the particle size at the minimum point (MIN2) existing on the side where the particle size is smaller relative to the third maximum point (MAX3) to the particle size at the minimum point existing on the side where the particle size is larger relative to the third maximum point (MAX3); or the integrated quantity of the frequency of from the particle size at the minimum point (MIN2) existing on the side where the particle size is smaller relative to the third maximum point (MAX3) to the particle size at the end (PE) of the particle size distribution on the side where the particle size is larger. Here, the reason for subtracting the frequency of the particle size at the minimum point existing on the side where the particle size is larger relative to the third maximum point (MAX3) is to prevent the frequency of the particle size at the minimum point existing on the side where the particle size is larger relative to the third maximum point (MAX3) from being included in both the integrated quantity of the frequency between the peak start and the peak end in the peak including the third maximum point (MAX3) and an integrated quantity of a frequency between a peak start and a peak end in a peak including a maximum point existing on the side where the particle size is larger relative to the third maximum point, adjacent to the third maximum point (MAX3).

In the boron nitride powder according to the present invention, the aggregated boron nitride particles have a crushing strength of preferably 5 to 18 MPa. When the aggregated boron nitride particles have a crushing strength of 5 MPa or more, the aggregated boron nitride particles can be prevented from being damaged during the manufacture of the heat dissipation sheet. When the aggregated boron nitride particles have a crushing strength of 18 MPa or less, resin can sufficiently enter the aggregated boron nitride particles in the heat dissipation sheet, and the air can be prevented from remaining in the aggregated boron nitride particles in the heat dissipation sheet. From the above viewpoints, in the boron nitride powder according to the present invention, the aggregated boron nitride particles have a crushing strength of preferably 6 to 15 MPa and more preferably 7 to 13 MPa. The crushing strength of the aggregated boron nitride particles can be measured by the method described in Examples described later.

As long as filling property of the boron nitride powder in the heat dissipation sheet can be improved, the particle size distribution of the boron nitride powder according to the present invention may have other maximum points in addition to the above first to third maximum points.

### [Method for Producing Boron Nitride Powder]

An example of the method for producing the boron nitride powder according to the present invention will be explained below.

The boron nitride powder according to the present invention can be produced by, for example, preparing each of first boron nitride powder having a particle size distribution including the first maximum point, second boron nitride powder having a particle size distribution including the second maximum point, and third boron nitride powder having a particle size distribution including the third maximum point, and mixing the prepared first to third boron nitride powders.

Among the first to third boron nitride powders, each of the second and third boron nitride powders is preferably boron nitride powder containing at least aggregated boron nitride particles formed by an aggregation of hexagonal boron nitride primary particles. The first boron nitride powder may be the aggregated boron nitride particles but is preferably the hexagonal boron nitride primary particles. The maximum point of each of the first to third boron nitride powders means a peak top in the particle size distribution of each of the first to third boron nitride powders. The particle size distributions of the first to third boron nitride powders are measured in the same manner as the particle size distribution of the boron nitride powder described above.

In the mixing step, the first to third boron nitride powders may be mixed such that the volume proportion of the third boron nitride powder becomes larger than the volume proportion of the second boron nitride powder and the volume proportion of the second boron nitride powder becomes larger than the volume proportion of the first boron nitride powder. In this way, filling property of the boron nitride powder can be more improved. The volume proportion of the third boron nitride powder is, relative to 100 parts by volume of the total of the first to third boron nitride powders, preferably 30 to 80 parts by volume, more preferably to 75 parts by volume, and further preferably 50 to 70 parts by volume, from a viewpoint of improving heat conductivity of the heat dissipation sheet. The volume proportion of the second boron nitride powder is, relative to 100 parts by volume of the total of the first to third boron nitride powders, preferably 15 to 50 parts by volume, more preferably 20 to 45 parts by volume, and further preferably to 35 parts by volume, from a viewpoint of improving heat conductivity of the heat dissipation sheet. The volume proportion of the first boron nitride powder is, relative to 100 parts by volume of the total of the first to third boron nitride powders, preferably 2 to 25 parts by volume, more preferably 5 to 20 parts by volume, and further preferably 8 to 15 parts by volume, from a viewpoint of improving heat conductivity of the heat dissipation sheet.

Each of the first to third boron nitride powders can be produced by, for example, a production method including a pulverization step of pulverizing a lump-shaped boron carbide, a nitridation step of nitriding the pulverized boron carbide to obtain boron carbonitride, and a decarburization step of decarburizing the boron carbonitride.

In the pulverization step, a lump-shaped carbon boron (boron carbide lump) is pulverized using a general pulverizer or disintegrator. Here, for example, boron carbide powder having a desired maximum point can be obtained by adjusting a pulverization time and a feeding amount of the boron carbide lump. The maximum point of the boron carbide powder can be measured in the same manner as the maximum point of the boron nitride powder described above. By adjusting the maximum point of the boron carbide powder to reach the desired maximum point of the boron nitride powder, the first to third boron nitride powders having the above-described maximum points can be obtained.

Next, in the nitridation step, boron carbonitride is obtained by firing the boron carbide powder in an atmosphere advancing the nitridation reaction and under a pressurized condition.

The atmosphere in the nitridation step is an atmosphere advancing the nitridation reaction. It may be, for example, nitrogen gas, ammonia gas, etc., and may be one of these alone or a combination of two or more of these. The atmosphere is preferably nitrogen gas from viewpoints of the ease of nitridation and the cost. The nitrogen gas content of the atmosphere is preferably 95% by volume or more and more preferably 99.9% by volume or more.

The pressure in the nitridation step is preferably 0.6 MPa or more and more preferably 0.7 MPa or more, preferably 1.0 MPa or less and more preferably 0.9 MPa or less. The pressure is further preferably 0.7 to 1.0 MPa. Firing temperature in the nitridation step is preferably 1800° C. or more and more preferably 1900° C. or more, and is preferably 2400° C. or less and more preferably 2200° C. or less. The firing temperature is further preferably 1800 to 2200° C. The pressure condition and the firing temperature are preferably 1800° C. or more and 0.7 to 1.0 MPa because it is a condition advancing the nitridation of the boron carbide more suitably and being industrially appropriate, too.

Firing time in the nitridation step is appropriately selected in a range where the nitridation proceeds sufficiently, and is preferably 6 hours or more and more preferably 8 hours or more, and may be preferably 30 hours or less and more preferably 20 hours or less.

In the decarburization step, the boron carbonitride obtained in the nitridation step is subjected to a heat treatment of retaining in an atmosphere equal to or above normal pressure at a predetermined retaining temperature for a certain period. In this way, aggregated boron nitride particles formed by an aggregation of decarburized and crystallized hexagonal boron nitride primary particles can be obtained.

The atmosphere in the decarburization step is an atmosphere of normal pressure (atmospheric pressure) or a pressurized atmosphere. In the case of the pressurized atmosphere, the pressure may be, for example, 0.5 MPa or less and preferably 0.3 MPa or less.

In the decarburization step, for example, the temperature is raised to a predetermined temperature (temperature at which the decarburization can start) and it is then further raised to the retaining temperature at a predetermined rate. The predetermined temperature (temperature at which the decarburization can start) can be set according to the system, and, for example, may be 1000° C. or more and may be 1500° C. or less, and is preferably 1200° C. or less. The rate at which the temperature is raised from the predetermined temperature (temperature at which the decarburization can start) to the retaining temperature may be, for example, 5° C./min or less and preferably 4° C./min or less, 3° C./min or less, or 2° C./min or less.

The retaining temperature is preferably 1800° C. or more and more preferably 2000° C. or more from viewpoints that a particle growth is ready to occur favorably and heat conductivity of the boron nitride powder obtained can be more improved. The retaining temperature may be preferably 2200° C. or less and more preferably 2100° C. or less.

A retaining time at the retaining temperature is appropriately selected in a range where the crystallization proceeds sufficiently, and may be, for example, more than 0.5 hours. It is preferably 1 hour or more, more preferably 3 hours or more, further preferably 5 hours or more, and particularly preferably 10 hours or more, from a viewpoint that a particle growth is ready to occur favorably. The retaining time at the retaining temperature may be, for example, less than 40 hours. It is preferably 30 hours or less and more preferably 20 hours or less, from viewpoints of preventing the particle growth from proceeding too much to decrease particle strength and reducing the cost.

In the decarburization step, a boron source may be mixed as a raw material in addition to the boron carbonitride obtained in the nitridation step to perform decarburization and crystallization. Examples of the boron source include boric acid, boron oxide, and a mixture thereof. In this case, other additives used in the art may be further used if necessary.

A mixing ratio of the boron carbonitride and the boron source is selected appropriately. When boric acid or boron oxide is used as the boron source, the ratio of the boric acid or the boron oxide may be, for example, 100 parts by mass or more and is preferably 150 parts by mass or more relative to 100 parts by mass of the boron carbonitride. It may be, for example, 300 parts by mass or less and is preferably 250 parts by mass or less relative to 100 parts by mass of the boron carbonitride.

The boron nitride powder obtained as the above may be subjected to a step of classification (classification step) using a sieve such that boron nitride powder having a desired particle size distribution can be obtained. In this way, the first to third boron nitride powders having the desired maximum points can be more suitably obtained.

By mixing the obtained first to third boron nitride powders, the boron nitride powder according to the present invention can be obtained. A mixing method is not particularly limited as long as it can mix the first to third boron nitride powders uniformly. For example, the first to third boron nitride powders may be mixed using a container rotating mixer, the first to third boron nitride powders may be mixed using a fixed container mixer, or the first to third boron nitride powders may be mixed using a fluid motion mixer.

### [Heat Dissipation Sheet]

A heat dissipation sheet according to the present invention is obtained by molding a heat conductive resin composition containing the boron nitride powder according to the present invention and a resin.

### (Resin)

Examples of the resin of the heat conductive resin composition include an epoxy resin, a silicone resin (including a silicone rubber), an acrylic resin, a phenolic resin, a melamine resin, a urea resin, an unsaturated polyester, a fluorine resin, a polyamide (for example, a polyimide, a polyamide imide, a polyether imide, etc.), a polyester (for example, a polybutylene terephthalate, a polyethylene terephthalate, etc.), a polyphenylene ether, a polyphenylene sulfide, a wholly aromatic polyester, a polysulfone, a liquid crystal polymer, a polyether sulfone, a polycarbonate, a maleimide-modified resin, an ABS resin, an AAS (acrylonitrile-acrylic rubber-styrene) resin, and an AES (acrylonitrile-ethylene-propylene-diene rubber-styrene) resin. Among these, a silicone resin is preferred from viewpoints of heat resistance, flexibility, and adhesiveness to a heat sink or the like. The silicone resin is preferably vulcanized with an organic peroxide to be cured. The heat conductive resin composition has a viscosity at 25° C. of, for example, 100,000 cp or less from a viewpoint of improving flexibility of a sheet-shaped molded body.

In the heat conductive resin composition, the boron nitride powder has a content relative to 100% by volume of the total of the boron nitride powder and the resin of preferably 30 to 85% by volume and more preferably 40 to 80% by volume. When the boron nitride powder has a content of 30% by volume or more, heat conductivity improves and a sufficient heat dissipation property is ready to be obtained. When the boron nitride powder has a content of 85% by volume or less, the tendency of voids to form during molding can be reduced and the deterioration of insulation property and mechanical strength can be reduced. The resin has a content relative to 100% by volume of the total of the boron nitride powder and the resin of preferably 15 to 70% by volume and more preferably 20 to 60% by volume.

### (Solvent)

The heat conductive resin composition may further contain solvent to adjust the viscosity of the heat conductive resin composition. The solvent is not particularly limited as long as it can dissolve the resin and, after applying the heat conductive resin composition, be easily removed from the applied heat conductive resin composition. When the resin is a silicone resin, examples of the solvent include toluene, xylene, and a chlorinated hydrocarbon. Among these solvents, toluene is preferred in a viewpoint of easiness of the removal. A content of the solvent can be selected appropriately according to the aimed viscosity of the heat conductive resin composition. The content of the solvent is, for example, 40 to 200 parts by mass relative to 100 parts by mass of the components of the heat conductive resin composition except for the solvent.

The heat conductive resin composition may contain other components than the boron nitride powder, the resin component, and the solvent. Examples of the other components include an inorganic filler other than the boron nitride powder, an additive, and an impurity. The other components have a content of preferably 5 parts by mass or less, more preferably 3 parts by mass or less, and further preferably 1 part by mass or less relative to 100 parts by mass of the total of the boron nitride powder and the resin.

### (Thickness of Heat Dissipation Sheet)

The heat dissipation sheet according to the present invention has a thickness of preferably 100 to 1200 μm. When the heat dissipation sheet has a thickness of 100 μm or more, the heat dissipation sheet can more securely adhere to heat generating electronic components. When the heat dissipation sheet has a thickness of 1200 μm or less, the heat dissipation property of the heat dissipation sheet can become more favorably. From the above viewpoints, the heat dissipation sheet according to the present invention has a thickness of more preferably 150 to 800 μm and further preferably 200 to 600 μm.

### [Method for Producing Heat Dissipation Sheet]

A method for producing the heat dissipation sheet according to the present invention includes a step (A) of blending the boron nitride powder according to the present invention and a resin to prepare a heat conductive resin composition, a step (B) of molding the heat conductive resin composition into a sheet shape to prepare a heat conductive resin composition sheet, and a step (C) of heating and pressurizing the heat conductive resin composition sheet under a vacuum.

### (Step (A))

In the step (A), the boron nitride powder according to the present invention and the resin are blended to prepare the heat conductive resin composition. The boron nitride powder and the resin used in the step (A) were already explained and therefore their explanation is omitted.

### (Step (B))

In the step (B), the heat conductive resin composition is molded into a sheet shape to prepare a heat conductive resin composition sheet. The heat conductive resin composition can be molded into a sheet shape by, for example, a doctor blade method or a calendering. However, when the heat conductive resin composition passes through calender rolls, a part of the aggregated boron nitride particles may fall off from the aggregated boron nitride particles in the heat conductive resin composition. Therefore, the heat conductive resin composition is preferably molded into a sheet shape with the doctor blade method.

### (Step (C))

In the step (C), the heat conductive resin composition sheet is heated and pressurized under vacuum. In this way, filling property of the boron nitride powder in the heat dissipation sheet can be more improved and heat conductivity of the heat dissipation sheet can be made more excellent. In addition, since microvoids in the heat dissipation sheet can be reduced accordingly, heat conductivity of the heat dissipation sheet can be made more excellent and the insulation property of the heat dissipation sheet can be improved. From the viewpoints of improvement in the filling property of the boron nitride powder and the reduction of the microvoids in the heat dissipation sheet, the pressure in the vacuum environment during heating and pressurizing the heat conductive resin composition sheet is preferably 0.1 to 5 kPa and more preferably 0.1 to 3 kPa. A heating temperature of the heat conductive resin composition sheet is preferably 120 to 200° C. and more preferably 130 to 180° C. A pressure at which the heat conductive resin composition sheet is pressurized is preferably 80 to 250 kg/cm² and more preferably 100 to 200 kg/cm².

### EXAMPLES

The present invention will be explained below in detail with reference to Examples and Comparative Examples. The present invention is not limited to the following Examples.

### (Particle Size Distribution)

The particle size distribution of the boron nitride powder was measured using a laser diffraction scattering particle size analyzer (LS-13 320) manufactured by Beckman Coulter, Inc. From the obtained particle size distribution, particle sizes at the first to third maximum points (first to third maximum values), integrated quantities of frequency (first to third integrated quantities of frequency) between the peak start and the peak end in the peaks including the first to third maximum points, the absolute value (distance between D10 and the first minimum value) of the difference between the particle size at which the integrated quantity of the frequency reaches 10%, and the particle size at the minimum point between the maximum point at which the particle size is the smallest and the maximum point at which the particle size is the second smallest, the absolute value (distance between the minimum values) of the difference between the particle size at the first minimum point and the particle size at the second minimum point, and the half-value width (half-value width of maximum value 3) of the peak including the third maximum point were obtained.

### (Crushing Strength)

Crushing strength of the aggregated boron nitride particles was measured in accordance with JIS R1639-5: 2007. Specifically, the aggregated boron nitride particles were scattered on a sample stage of a microcompression tester (“MCT-W500” manufactured by Shimadzu Corporation), five aggregated boron nitride particles were selected, and each one particle was subjected to a compression test. Then, crushing strength (σ: MPa) was calculated by a formula σ=α×P/(π×d²) from a dimensionless number (α=2.48) variable according to a position in the particle, crushing test force (P:N), and a particle size (d:μm). The crushing strengths of five inorganic filler components were subjected to Weibull plotting in accordance with JIS R1625: 2010 and crushing strength at which a cumulative damage rate reached 63.2% was determined as the crushing strength of the aggregated boron nitride particles.

Evaluations below were performed on the heat dissipation sheets of Examples and Comparative Examples.

### (Insulation Property)

A dielectric breakdown voltage of the heat dissipation sheet was evaluated based on a value measured in accordance with the method described in JIS C2110-1: 2016 by a short-time breakdown test (room temperature: 23° C.). The results are shown in Table 1.

Evaluation criterion for insulation property is equal to or less than the thickness.
⊚: dielectric breakdown voltage is 10 kV or more
◯: dielectric breakdown voltage is 5 kV or more and less than 10 kV
x: dielectric breakdown voltage is less than 5 kV

### (Heat Conductivity)

A heat resistance of the heat dissipation sheet was evaluated based on a value measured in accordance with the method described in ASTM D5470: 2017. The results are shown in Table 1.

Evaluation criterion for heat conductivity is as below.
⊚: heat conductivity is 5 W/(m·K) or more
◯: heat conductivity is 3 W/(m·K) or more and less than 5 W/(m·K)
x: heat conductivity is less than 3 W/(m K)

Boron nitride powders A to W having one maximum point as a raw material of the boron nitride powder having the plural maximum points were prepared as below.

### (Boron Nitride Powder A)

Boron nitride powder A was prepared through a boron carbide synthesis, a pressurized nitridation step, and a decarburization-crystallization step as below.

### (Boron Carbide Synthesis)

100 parts by mass of orthoboric acid (hereinafter, boric acid) manufactured by Nippon Denko Co., Ltd. and 35 parts by mass of acetylene black (HS100) manufactured by Denka Company Limited were mixed using a Henschel mixer. The obtained mixture was filled in a graphite crucible and heated in an arc furnace in an argon atmosphere at 2200° C. for 5 hours to synthesize boron carbide (B₄C). The synthesized boron carbide lump was pulverized with a ball mill for 3 hours, sieved with a sieve mesh into a particle size of 75 μm or less, washed with aqueous nitric acid solution to remove impurities such as iron, and filtered and dried to prepare boron carbide powder having an average particle size of 0.5 μm.

### (Pressurized Nitridation Step)

The synthesized boron carbide was filled in a boron nitride crucible and then heated using a resistance heating furnace in a nitrogen gas atmosphere under the conditions of 2000° C. and 9 atmospheres (0.8 MPa) for 10 hours to obtain boron carbonitride (B₄CN₄).

### (Decarburization-Crystallization Step)

100 parts by mass of the synthesized boron carbonitride and 90 parts by mass of boric acid were mixed using a Henschel mixer. The obtained mixture was filled in a boron nitride crucible, the temperature was raised at a rate of 10° C./min from the room temperature to 1000° C. and at a rate of 2° C./min from 1000° C. using a resistance heating furnace under the pressure condition of 0.2 MPa in a nitrogen gas atmosphere, and heating was performed at a firing temperature of 2020° C. for a retaining time of 10 hours to synthesize aggregated boron nitride particles in a lump shape formed by an aggregation of primary particles. The synthesized aggregated boron nitride particles were disintegrated with a Henschel mixer for 15 minutes, and classified using a sieve mesh and with a nylon sieve having a sieve opening of 150 μm. Boron nitride powder A was obtained by disintegrating and classifying the fired product.

The average particle size (D50) of the obtained boron nitride powder A measured by a laser scattering method was 1.0 μm. According to an SEM observation, the obtained boron nitride powder A was scaly particles.

### (Boron Nitride Powder B)

Boron nitride powder B was prepared in the same manner as the boron nitride powder A except that the synthesized boron carbide lump was pulverized with a ball mill for 2 hours and boron carbide powder having an average particle size of 1 μm was used. The average particle size (D50) of the obtained boron nitride powder B measured by a laser scattering method was 2.0 μm. According to an SEM observation, the obtained boron nitride powder B was scaly particles.

### (Boron Nitride Powder C)

Boron nitride powder C was prepared in the same manner as the boron nitride powder A except that the synthesized boron carbide lump was pulverized with a ball mill for 1 hour and boron carbide powder having an average particle size of 2 μm was used. The average particle size (D50) of the obtained boron nitride powder C measured by a laser scattering method was 3.0 μm. According to an SEM observation, the obtained boron nitride powder C was scaly particles.

### (Boron Nitride Powder D)

Boron nitride powder D was prepared in the same manner as the boron nitride powder A except that the synthesized boron carbide lump was pulverized with a ball mill for 0.5 hours and boron carbide powder having an average particle size of 3 μm was used. The average particle size (D50) of the obtained boron nitride powder D measured by a laser scattering method was 4.5 μm. According to an SEM observation, the obtained boron nitride powder D was scaly particles.

### (Boron Nitride Powder E)

Boron nitride powder E was prepared in the same manner as the boron nitride powder A except that boron carbide powder having an average particle size of 5 μm was used. The average particle size (D50) of the obtained boron nitride powder E measured by a laser scattering method was 8.0 μm. According to an SEM observation, the obtained boron nitride powder E was scaly particles.

### (Boron Nitride Powder F)

Boron nitride powder F was prepared in the same manner as the boron nitride powder A except that boron carbide powder having an average particle size of 10 μm was used. The average particle size (D50) of the obtained boron nitride powder F measured by a laser scattering method was 15 μm. According to an SEM observation, the obtained boron nitride powder F was aggregated particles formed by an aggregation of primary particles.

### (Boron Nitride Powder G)

Boron nitride powder G was prepared in the same manner as the boron nitride powder A except that boron carbide powder having an average particle size of 15 μm was used. The average particle size (D50) of the obtained boron nitride powder G measured by a laser scattering method was 20 μm. According to an SEM observation, the obtained boron nitride powder G was aggregated particles formed by an aggregation of primary particles.

### (Boron Nitride Powder H)

Boron nitride powder H was prepared in the same manner as the boron nitride powder A except that boron carbide powder having an average particle size of 20 μm was used. The average particle size (D50) of the obtained boron nitride powder H measured by a laser scattering method was 25 μm. According to an SEM observation, the obtained boron nitride powder H was aggregated particles formed by an aggregation of primary particles.

### (Boron Nitride Powder I)

Boron nitride powder I was prepared in the same manner as the boron nitride powder A except that boron carbide powder having an average particle size of 25 μm was used. The average particle size (D50) of the obtained boron nitride powder I measured by a laser scattering method was 30 μm. According to an SEM observation, the obtained boron nitride powder I was aggregated particles formed by an aggregation of primary particles.

### (Boron Nitride Powder J)

Boron nitride powder J was prepared in the same manner as the boron nitride powder A except that boron carbide powder having an average particle size of 30 μm was used. The average particle size (D50) of the obtained boron nitride powder J measured by a laser scattering method was 36 μm. According to an SEM observation, the obtained boron nitride powder J was aggregated particles formed by an aggregation of primary particles.

### (Boron Nitride Powder K)

Boron nitride powder K was prepared in the same manner as the boron nitride powder A except that boron carbide powder having an average particle size of 33 μm was used. The average particle size (D50) of the obtained boron nitride powder K measured by a laser scattering method was 38 μm. According to an SEM observation, the obtained boron nitride powder K was aggregated particles formed by an aggregation of primary particles.

### (Boron Nitride Powder L)

Boron nitride powder L was prepared in the same manner as the boron nitride powder A except that boron carbide powder having an average particle size of 40 μm was used. The average particle size (D50) of the obtained boron nitride powder L measured by a laser scattering method was 55 μm. According to an SEM observation, the obtained boron nitride powder L was aggregated particles formed by an aggregation of primary particles.

### (Boron Nitride Powder M)

Boron nitride powder M was prepared in the same manner as the boron nitride powder A except that boron carbide powder having an average particle size of 27 μm was used. The average particle size (D50) of the obtained boron nitride powder M measured by a laser scattering method was 32 μm. According to an SEM observation, the obtained boron nitride powder M was aggregated particles formed by an aggregation of primary particles. The peak of the particle size distribution of the boron nitride powder M had a half-value width of 26 μm.

### (Boron Nitride Powder N)

Boron nitride powder N was prepared in the same manner as the boron nitride powder A except that boron carbide powder having an average particle size of 40 μm was used. The average particle size (D50) of the obtained boron nitride powder N measured by a laser scattering method was 48 μm. According to an SEM observation, the obtained boron nitride powder N was aggregated particles formed by an aggregation of primary particles. The peak of the particle size distribution of the boron nitride powder N had a half-value width of 24 μm.

### (Boron Nitride Powder 0)

Boron nitride powder 0 was prepared in the same manner as the boron nitride powder A except that boron carbide powder having an average particle size of 43 μm was used. The average particle size (D50) of the obtained boron nitride powder 0 measured by a laser scattering method was 50 μm. According to an SEM observation, the obtained boron nitride powder 0 was aggregated particles formed by an aggregation of primary particles. The peak of the particle size distribution of the boron nitride powder 0 had a half-value width of 52 μm.

### (Boron Nitride Powder P)

Boron nitride powder P was prepared in the same manner as the boron nitride powder A except that boron carbide powder having an average particle size of 45 μm was used. The average particle size (D50) of the obtained boron nitride powder P measured by a laser scattering method was 55 μm. According to an SEM observation, the obtained boron nitride powder P was aggregated particles formed by an aggregation of primary particles. The peak of the particle size distribution of the boron nitride powder P had a half-value width of 26 μm.

### (Boron Nitride Powder Q)

Boron nitride powder Q was prepared in the same manner as the boron nitride powder A except that boron carbide powder having an average particle size of 70 μm was used and sieving to 150 μm or less was performed. The average particle size (D50) of the obtained boron nitride powder Q measured by a laser scattering method was 78 μm. According to an SEM observation, the obtained boron nitride powder Q was aggregated particles formed by an aggregation of primary particles. The peak of the particle size distribution of the boron nitride powder Q had a half-value width of 46 μm.

### (Boron Nitride Powder R)

Boron nitride powder R was prepared in the same manner as the boron nitride powder A except that boron carbide powder having an average particle size of 65 μm was used and sieving to 150 μm or less was performed. The average particle size (D50) of the obtained boron nitride powder R measured by a laser scattering method was 88 μm. According to an SEM observation, the obtained boron nitride powder R was aggregated particles formed by an aggregation of primary particles. The peak of the particle size distribution of the boron nitride powder R had a half-value width of 15 μm.

### (Boron Nitride Powder 5)

Boron nitride powder S was prepared in the same manner as the boron nitride powder A except that boron carbide powder having an average particle size of 70 μm was used and sieving to 75 μm or more and 150 μm or less was performed. The average particle size (D50) of the obtained boron nitride powder S measured by a laser scattering method was 90 μm. According to an SEM observation, the obtained boron nitride powder S was aggregated particles formed by an aggregation of primary particles. The peak of the particle size distribution of the boron nitride powder S had a half-value width of 55 μm.

### (Boron Nitride Powder T)

Boron nitride powder T was prepared in the same manner as the boron nitride powder A except that boron carbide powder having an average particle size of 38 μm was used and sieving to 150 μm or less was performed. The average particle size (D50) of the obtained boron nitride powder T measured by a laser scattering method was 90 μm. According to an SEM observation, the obtained boron nitride powder T was aggregated particles formed by an aggregation of primary particles. The peak of the particle size distribution of the boron nitride powder T had a half-value width of 38 μm.

### (Boron Nitride Powder U)

Boron nitride powder U was prepared in the same manner as the boron nitride powder A except that boron carbide powder having an average particle size of 75 μm was used. The average particle size (D50) of the obtained boron nitride powder U measured by a laser scattering method was 100 μm. According to an SEM observation, the obtained boron nitride powder U was aggregated particles formed by an aggregation of primary particles. The peak of the particle size distribution of the boron nitride powder U had a half-value width of 31 μm.

### (Boron Nitride Powder V)

Boron nitride powder V was prepared in the same manner as the boron nitride powder A except that boron carbide powder having an average particle size of 115 μm was used. The average particle size (D50) of the obtained boron nitride powder V measured by a laser scattering method was 150 μm. According to an SEM observation, the obtained boron nitride powder V was aggregated particles formed by an aggregation of primary particles. The peak of the particle size distribution of the boron nitride powder V had a half-value width of 35 μm.

Boron nitride powders A to V were mixed at the blending ratio shown in Table 1 and Table 2 to prepare boron nitride powders 1 to 18.

TABLE 1

| | Boron nitride | Boron nitride | Boron nitride | Boron nitride | Boron nitride | Boron nitride |
|---|---|---|---|---|---|---|
| Boron nitride powder | powder 1 | powder 2 | powder 3 | powder 4 | powder 5 | powder 6 |
| raw material | Ex. | Ex. | Ex. | Ex. | Ex. | Ex. |
| Boron nitride powder | — | — | — | — | — | — |
| A (parts by volume) | | | | | | |
| Boron nitride powder | 10 | — | — | — | — | — |
| B (parts by volume) | | | | | | |
| Boron nitride powder | — | — | — | — | — | — |
| C (parts by volume) | | | | | | |
| Boron nitride powder | — | — | 10 | 10 | 10 | 10 |
| D (parts by volume) | | | | | | |
| Boron nitride powder | — | 10 | — | — | — | — |
| E (parts by volume) | | | | | | |
| Boron nitride powder | — | — | 25 | — | — | — |
| F (parts by volume) | | | | | | |
| Boron nitride powder | — | — | — | — | — | — |
| G (parts by volume) | | | | | | |
| Boron nitride powder | — | — | — | — | — | — |
| H (parts by volume) | | | | | | |
| Boron nitride powder | 25 | 25 | — | — | 25 | 25 |
| I (parts by volume) | | | | | | |
| Boron nitride powder | — | — | — | 25 | — | — |
| J (parts by volume) | | | | | | |
| Boron nitride powder | — | — | — | — | — | — |
| K (parts by volume) | | | | | | |
| Boron nitride powder | — | — | — | — | — | — |
| L (parts by volume) | | | | | | |
| Boron nitride powder | — | — | — | — | — | — |
| M (parts by volume) | | | | | | |
| Boron nitride powder | — | — | — | — | — | — |
| N (parts by volume) | | | | | | |
| Boron nitride powder | — | — | — | — | — | 65 |
| O (parts by volume) | | | | | | |
| Boron nitride powder | — | — | — | — | — | — |
| P (parts by volume) | | | | | | |
| Boron nitride powder | 65 | 65 | 65 | 65 | — | — |
| Q (parts by volume) | | | | | | |
| Boron nitride powder | — | — | — | — | — | — |
| R (parts by volume) | | | | | | |
| Boron nitride powder | — | — | — | — | — | — |
| S (parts by volume) | | | | | | |
| Boron nitride powder | — | — | | — | — | — |
| T (parts by volume) | | | | | | |
| Boron nitride powder | — | — | — | — | 65 | — |
| U (parts by volume) | | | | | | |
| Boron nitride powder | — | — | — | — | — | — |
| V (parts by volume) | | | | | | |
| | Boron nitride | Boron nitride | Boron nitride | Boron nitride | Boron nitride | Boron nitride |
| Boron nitride powder | powder 7 | powder 8 | powder 9 | powder 10 | powder 11 | powder 12 |
| raw material | Ex. | Ex. | Ex. | Ex. | Ex. | Ex. |
| Boron nitride powder | 5 | — | — | — | — | — |
| A (parts by volume) | | | | | | |
| Boron nitride powder | — | — | — | — | | — |
| B (parts by volume) | | | | | | |
| Boron nitride powder | — | — | 5 | — | 5 | — |
| C (parts by volume) | | | | | | |
| Boron nitride powder | — | — | — | — | — | 5 |
| D (parts by volume) | | | | | | |
| Boron nitride powder | — | 5 | — | 20 | — | — |
| E (parts by volume) | | | | | | |
| Boron nitride powder | — | — | — | — | — | — |
| F (parts by volume) | | | | | | |
| Boron nitride powder | — | 40 | — | 20 | — | — |
| G (parts by volume) | | | | | | |
| Boron nitride powder | — | — | 40 | — | — | — |
| H (parts by volume) | | | | | | |
| Boron nitride powder | — | — | — | — | 20 | 20 |
| I (parts by volume) | | | | | | |
| Boron nitride powder | — | — | — | — | — | — |
| J (parts by volume) | | | | | | |
| Boron nitride powder | 40 | — | — | — | — | — |
| K (parts by volume) | | | | | | |
| Boron nitride powder | — | — | — | 60 | — | — |
| L (parts by volume) | | | | | | |
| Boron nitride powder | — | — | — | — | — | — |
| M (parts by volume) | | | | | | |
| Boron nitride powder | — | — | — | — | 75 | — |
| N (parts by volume) | | | | | | |
| Boron nitride powder | — | — | — | — | — | — |
| O (parts by volume) | | | | | | |
| Boron nitride powder | — | — | — | — | — | — |
| P (parts by volume) | | | | | | |
| Boron nitride powder | 55 | 55 | — | — | — | — |
| Q (parts by volume) | | | | | | |
| Boron nitride powder | — | — | — | — | — | — |
| R (parts by volume) | | | | | | |
| Boron nitride powder | — | — | — | — | — | 75 |
| S (parts by volume) | | | | | | |
| Boron nitride powder | — | — | 55 | — | — | — |
| T (parts by volume) | | | | | | |
| Boron nitride powder | — | — | — | — | — | — |
| U (parts by volume) | | | | | | |
| Boron nitride powder | — | — | — | — | — | — |
| V (parts by volume) | | | | | | |

TABLE 2

| | Boron nitride | Boron nitride | Boron nitride | Boron nitride | Boron nitride | Boron nitride |
|---|---|---|---|---|---|---|
| Boron nitride powder | powder 13 | powder 14 | powder 15 | powder 16 | powder 17 | powder 18 |
| raw material | Comp. Ex. | Comp. Ex. | Comp. Ex. | Comp. Ex. | Comp. Ex. | Ex. |
| Boron nitride powder | — | — | — | — | — | — |
| A (parts by volume) | | | | | | |
| Boron nitride powder | — | — | — | — | — | — |
| B (parts by volume) | | | | | | |
| Boron nitride powder | — | — | — | — | — | — |
| C (parts by volume) | | | | | | |
| Boron nitride powder | — | — | 5 | 10 | 15 | 5 |
| D (parts by volume) | | | | | | |
| Boron nitride powder | — | — | — | — | — | — |
| E (parts by volume) | | | | | | |
| Boron nitride powder | 10 | — | — | — | — | — |
| F (parts by volume) | | | | | | |
| Boron nitride powder | — | — | — | — | — | — |
| G (parts by volume) | | | | | | |
| Boron nitride powder | — | — | — | — | — | — |
| H (parts by volume) | | | | | | |
| Boron nitride powder | 25 | 25 | — | 30 | 15 | 10 |
| I (parts by volume) | | | | | | |
| Boron nitride powder | — | — | — | — | — | — |
| J (parts by volume) | | | | | | |
| Boron nitride powder | — | — | — | — | — | — |
| K (parts by volume) | | | | | | |
| Boron nitride powder | — | — | 30 | — | — | — |
| L (parts by volume) | | | | | | |
| Boron nitride powder | — | — | — | — | 70 | — |
| M (parts by volume) | | | | | | |
| Boron nitride powder | — | — | — | — | — | — |
| N (parts by volume) | | | | | | |
| Boron nitride powder | — | — | — | — | — | — |
| O (parts by volume) | | | | | | |
| Boron nitride powder | — | — | — | — | — | — |
| P (parts by volume) | | | | | | |
| Boron nitride powder | 65 | 75 | 65 | — | — | — |
| Q (parts by volume) | | | | | | |
| Boron nitride powder | — | — | — | — | — | 85 |
| R (parts by volume) | | | | | | |
| Boron nitride powder | — | — | — | — | — | — |
| S (parts by volume) | | | | | | |
| Boron nitride powder | — | — | — | — | — | — |
| T (parts by volume) | | | | | | |
| Boron nitride powder | — | — | — | — | — | — |
| U (parts by volume) | | | | | | |
| Boron nitride powder | — | — | — | 60 | — | — |
| V (parts by volume) | | | | | | |

### (Preparation of Heat Dissipation Sheet)

60% by volume of the obtained boron nitride powder and 40% by volume of liquid silicone resin 1 (methyl vinyl polysiloxane manufactured by Dow Toray Co., Ltd., trade name “CF-3110”) relative to 100% by volume of the total of the boron nitride powder and the liquid silicone resin; 1 part by mass of a curing agent (2,5-dimethyl-2,5-bis(t-butylperoxy)hexane manufactured by Kayaku Nouryon Corporation, trade name “Trigonox 101”) relative to 100 parts by mass of the silicone resin; 0.5 parts by mass of a silane coupling agent (dimethyldimethoxysilane manufactured by Dow Toray Co., Ltd., trade name “DOWSIL Z-6329 Silane”, viscosity at 25° C.: 1 cp) relative to 100 parts by mass of the total of the boron nitride powder; 15 parts by mass of water relative to 100 parts by mass of the silane coupling agent; and 110 parts by mass of toluene relative to 100 parts by mass of the total of the above raw materials were charged into an agitator (manufactured by HEIDON, trade name “Three-One Motor”) and mixed using a turbine type agitation blade for 15 hours to prepare slurry of the heat conductive resin composition.

Then, the slurry was applied on a PET film (carrier film) having a thickness of 0.05 mm by the doctor blade method in a thickness of 1.0 mm and dried at 75° C. for 5 minutes to prepare a sheet-shaped molded body having a PET film attached. On a surface of the heat conductive resin composition side of the sheet-shaped molded body having a PET film attached, a PET film having a thickness of 0.05 mm was laminated to prepare a laminated body. The laminated body had a layer structure of PET film-heat conductive resin composition-PET film. Next, the obtained laminated body was subjected to a heat press in vacuum (pressure: 3.5 kPa) under the conditions of the temperature being 150° C. and the pressure being 160 kg/cm 2 for 30 minutes. The PET films on the both surfaces were peeled off to obtain a sheet having a thickness of 1.0 mm. Thereafter, the sheet was secondarily heated at normal pressure at 150° C. for 4 hours to obtain the heat dissipation sheet.

The evaluation results of the obtained boron nitride powders and heat dissipation sheets are shown in Tables 3 and 4.

TABLE 3

| | | Heat | Heat | Heat | Heat | Heat | Heat |
|---|---|---|---|---|---|---|---|
| | | dissipation | dissipation | dissipation | dissipation | dissipation | dissipation |
| | | sheet 1 | sheet 2 | sheet 3 | sheet 4 | sheet 5 | sheet 6 |
| | | Ex. | Ex. | Ex. | Ex. | Ex. | Ex. |
| | | Boron | Boron | Boron | Boron | Boron | Boron |
| | | nitride | nitride | nitride | nitride | nitride | nitride |
| Boron nitride powder | | powder 1 | powder 2 | powder 3 | powder 4 | powder 5 | powder 6 |
| Evaluation | First max. value (μm) | 2 | 8 | 4.5 | 4.5 | 4.5 | 4.5 |
| results of | Second max. value | 30 | 30 | 15 | 36 | 30 | 30 |
| boron | (μm) | | | | | | |
| nitride | Third max. value | 78 | 78 | 78 | 78 | 100 | 50 |
| powder | (μm) | | | | | | |
| | First integrated | 10 | 10 | 10 | 10 | 10 | 10 |
| | quantity of frequency | | | | | | |
| | (% by volume) | | | | | | |
| | Second integrated | 25 | 25 | 25 | 25 | 25 | 25 |
| | quantity of frequency | | | | | | |
| | (% by volume) | | | | | | |
| | Third integrated | 65 | 65 | 65 | 65 | 65 | 65 |
| | quantity of frequency | | | | | | |
| | (% by volume) | | | | | | |
| | Distance between | 14 | 11 | 6 | 16 | 12 | 12 |
| | D10 and first min. | | | | | | |
| | value (μm) | | | | | | |
| | Distance between | 38 | 35 | 36 | 36 | 45 | 23 |
| | min. values (μm) | | | | | | |
| | Half-value width of | 46 | 46 | 46 | 46 | 31 | 52 |
| | max. value 3 (μm) | | | | | | |
| | Crushing strength | 8 | 6 | 7 | 10 | 15 | 8 |
| | (MPa) | | | | | | |
| Evaluation | Thickness (mm) | 0.4 | 0.4 | 0.4 | 0.4 | 0.4 | 0.4 |
| results of | Insulation property | A | A | A | A | A | B |
| heat | Heat conductivity | A | B | A | B | B | A |
| dissipation | | | | | | | |
| sheet | | | | | | | |
| | | Heat | Heat | Heat | Heat | Heat | Heat |
| | | dissipation | dissipation | dissipation | dissipation | dissipation | dissipation |
| | | sheet 7 | sheet 8 | sheet 9 | sheet 10 | sheet 11 | sheet 12 |
| | | Ex. | Ex. | Ex. | Ex. | Ex. | Ex. |
| | | Boron | Boron | Boron | Boron | Boron | Boron |
| | | nitride | nitride | nitride | nitride | nitride | nitride |
| Boron nitride powder | | powder 7 | powder 8 | powder 9 | powder 10 | powder 11 | powder 12 |
| Evaluation | First max. value (μm) | 1 | 8 | 3 | 8 | 4.5 | 4.5 |
| results of | Second max. value | 38 | 20 | 25 | 20 | 30 | 30 |
| boron | (μm) | | | | | | |
| nitride | Third max. value | 78 | 78 | 90 | 55 | 48 | 90 |
| powder | (μm) | | | | | | |
| | First integrated | 5 | 5 | 5 | 20 | 5 | 5 |
| | quantity of frequency | | | | | | |
| | (% by volume) | | | | | | |
| | Second integrated | 40 | 40 | 40 | 20 | 20 | 20 |
| | quantity of frequency | | | | | | |
| | (% by volume) | | | | | | |
| | Third integrated | 55 | 55 | 55 | 60 | 75 | 75 |
| | quantity of frequency | | | | | | |
| | (% by volume) | | | | | | |
| | Distance between | 24 | 5 | 12 | 6 | 9 | 9 |
| | D10 and first min. | | | | | | |
| | value (μm) | | | | | | |
| | Distance between | 39 | 35 | 53 | 19 | 25 | 41 |
| | min. values (μm) | | | | | | |
| | Half-value width of | 46 | 46 | 38 | 26 | 55 | 24 |
| | max. value 3 (μm) | | | | | | |
| | Crushing strength | 9 | 8 | 13 | 9 | 8 | 12 |
| | (MPa) | | | | | | |
| Evaluation | Thickness (mm) | 0.4 | 0.4 | 0.4 | 0.4 | 0.4 | 0.4 |
| results of | Insulation property | A | A | A | B | B | A |
| heat | Heat conductivity | A | B | B | A | A | B |
| dissipation | | | | | | | |
| sheet | | | | | | | |

TABLE 4

| | | Heat | Heat | Heat | Heat | Heat |
|---|---|---|---|---|---|---|
| | | dissipation | dissipation | dissipation | dissipation | dissipation |
| | | sheet 13 | sheet 14 | sheet 15 | sheet 16 | sheet 17 |
| | | Comp. Ex. | Comp. Ex. | Comp. Ex. | Comp. Ex. | Comp. Ex. |
| | | Boron | Boron | Boron | Boron | Boron |
| | | nitride | nitride | nitride | nitride | nitride |
| Boron nitride powder | | powder 13 | powder 14 | powder 15 | powder 16 | powder 17 |
| Evaluation | First max. value (μm) | 15 | — | 4.5 | 4.5 | 4.5 |
| results of | Second max. value (μm) | 30 | 30 | 55 | 30 | 30 |
| boron nitride | Third max. value (μm) | 78 | 78 | 78 | 150 | 32 |
| powder | First integrated quantity of | 10 | 0 | 5 | 10 | 15 |
| | frequency (% by volume) | | | | | |
| | Second integrated quantity of | 25 | 25 | 30 | 30 | 15 |
| | frequency (% by volume) | | | | | |
| | Third integrated quantity of | 65 | 75 | 65 | 60 | 70 |
| | frequency (% by volume) | | | | | |
| | Distance between D10 and | 7.5 | 23 | 25 | 13 | 12 |
| | first min. value (μm) | | | | | |
| | Distance between min. values | 32 | — | 36 | 71 | 12 |
| | (μm) | | | | | |
| | Half-value width of max. | 46 | 46 | 46 | 35 | 26 |
| | value 3 (μm) | | | | | |
| | Crushing strength (MPa) | 8 | 11 | 13 | 17 | 6 |
| Evaluation | Thickness (mm) | 0.4 | 0.4 | 0.4 | 0.4 | 0.4 |
| results of heat | Insulation property | C | C | C | C | B |
| dissipation | Heat conductivity | A | B | B | A | C |
| sheet | | | | | | |

From the evaluation results of the heat dissipation sheets of Examples, using the boron nitride powder in which the particle size at the first maximum point was 0.4 μm or more and less than 10 μm, the particle size at the second maximum point was 10 μm or more and less than 40 μm, and the particle size at the third maximum point was 40 μm or more and 110 μm or less was found to improve heat conductivity of the heat dissipation sheet. In addition, using the above boron nitride powder was also found to improve insulation property of the heat dissipation sheet.

1. A boron nitride powder, comprising at least an aggregated boron nitride particle formed by an aggregation of hexagonal boron nitride primary particles,
the boron nitride powder having a particle size distribution including at least a first maximum point, a second maximum point at which a particle size is larger than at the first maximum point, and a third maximum point at which a particle size is larger than at the second maximum point, wherein
the particle size at the first maximum point is 0.4 μm or more and less than 10 μm,
the particle size at the second maximum point is 10 μm or more and less than 40 μm, and
the particle size at the third maximum point is 40 μm or more and 110 μm or less.

2. The boron nitride powder according to claim 1, wherein an absolute value of a difference between a particle size at which an integrated quantity of a frequency in the particle size distribution of the boron nitride powder reaches 10%, and a particle size at a minimum point between a maximum point at which a particle size is the smallest and a maximum point at which a particle size is the second smallest in the particle size distribution of the boron nitride powder is 3 to 30 μm.

3. The boron nitride powder according to claim 1, wherein
a maximum point adjacent to the first maximum point is the second maximum point,
a maximum point adjacent to the second maximum point is the third maximum point, and
an absolute value of a difference between a particle size at a first minimum point existing between the first maximum point and the second maximum point, and a particle size at a second minimum point existing between the second maximum point and the third maximum point is 15 to 60 μm.

4. The boron nitride powder according to claim 1, wherein a peak including the third maximum point has a half-value width of 20 to 60 μm.

5. The boron nitride powder according to claim 1, wherein the aggregated boron nitride particle has a crushing strength of 5 to 18 MPa.

6. A heat dissipation sheet obtained by molding a heat conductive resin composition comprising the boron nitride powder according to claim 1 and a resin.

7. A method for producing a heat dissipation sheet, comprising
a step of blending the boron nitride powder according to claim 1 and a resin to prepare a heat conductive resin composition,
a step of molding the heat conductive resin composition into a sheet shape to prepare a heat conductive resin composition sheet, and
a step of heating and pressurizing the heat conductive resin composition sheet under a vacuum.
